(19) United States
(12) Patent Application Publication
(10) Pub. No.: US 2026/0012173 A1
(43) Pub. Date: Jan. 8, 2026

(54) BIDIRECTIONAL SWITCH DRIVER

(71) Applicant: Texas Instruments Incorporated, Dallas, TX (US)

(72) Inventors: Ujwal Radhakrishna, SAN JOSE, CA (US); Pilsung Park, Richardson, TX (US); Sandeep Bahl, PALO ALTO, CA (US); Chang Soo Suh, ALLEN, TX (US); Timothy Merkin, PRINCETON, TX (US)

(73) Assignee: Texas Instruments Incorporated, Dallas, TX (US)

(21) Appl. No.: 18/762,733

(22) Filed: Jul. 3, 2024

(51) Int. Cl. H03K 17/687; H01L 27/095; H01L 29/20; H01L 29/66; H01L 29/778

(52) U.S. Cl. CPC H03K 17/6871; H10D 30/015; H10D 30/475; H10D 62/8503; H10D 84/86

(57) ABSTRACT

In one example, a bidirectional switch driver includes a first driver circuit and a second driver circuit having inputs coupled to a control input of the bidirectional switch driver, the first driver circuit has a first driver output and a first reference terminal, and the second driver circuit has a second driver output and a second reference terminal. The first driver circuit is configured to, responsive to the control input, provide a first voltage difference or a second voltage difference between the first driver output and the first reference terminal. The second driver circuit is configured to, responsive to the control input, provide a third voltage difference between the second driver output and the second reference terminal, a magnitude of the third voltage difference being between respective magnitudes of the first and second voltage differences.

### BACKGROUND

A bidirectional switch can support bidirectional current flow between two current terminals when it is in the on state and can provide bidirectional voltage blocking between the two switch terminals when it is in the off state. A bidirectional switch may include two control terminals. The voltages at the control terminals and the current terminals can set the on/off states of the bidirectional switch, as well as other electrical properties of the bidirectional switch, such as on-state resistance and off-state leakage.

### SUMMARY

This Summary is provided to introduce examples of disclosed concepts in a simplified form, which are further described below in the Detailed Description including the drawings provided.

According to certain aspects, an apparatus comprises a bidirectional switch driver. The bidirectional switch driver has a control input and a first switch control output and a second switch control output. The bidirectional switch driver includes a first driver circuit and a second driver circuit. The first driver circuit has a first driver input coupled to the control input, a first driver output coupled to the first switch control output, and a first reference terminal. The second driver circuit has a second driver input coupled to the control input, a second driver output coupled to the second switch control output, and a second reference terminal. The first driver circuit is configured to, responsive to the control input, provide a first voltage difference or a second voltage difference between the first driver output and the first reference terminal. The second driver circuit is configured to, responsive to the control input, provide a third voltage difference between the second driver output and the second reference terminal, a magnitude of the third voltage difference being between respective magnitudes of the first and second voltage differences.

According to certain aspects, an apparatus comprises a first bidirectional switch, a second bidirectional switch, and a first bidirectional switch driver, and a second bidirectional switch driver. The first bidirectional switch is coupled between an alternating current (AC) terminal and a switching terminal, the first bidirectional switch having a first switch control terminal and a second switch control terminal. The second bidirectional switch is coupled between the switching terminal and a ground terminal, the second bidirectional switch having a third switch control terminal and a fourth switch control terminal. The first bidirectional switch driver has a first driver input, a first driver output, a first reference terminal, a second driver output, and a second reference terminal, the first driver output coupled to the switch control terminal, the second driver output coupled to the switch control terminal, the first reference terminal coupled to the AC terminal, and the second reference terminal coupled to the switching terminal. The first bidirectional switch driver is configured to: provide a first voltage difference or a second voltage difference between the first driver output and the first reference terminal responsive to a state of the first driver input; and provide a third voltage difference between the second driver output and the second reference terminal, a magnitude of the third voltage difference being between respective magnitudes of the first and second voltage difference. The second bidirectional switch driver has a second driver input, a third driver output, a third reference terminal, a fourth driver output, and a fourth reference terminal, the third driver output coupled to the third switch control terminal, the fourth driver output coupled to the fourth switch control terminal, the third reference terminal coupled to the switching terminal, and the fourth reference terminal coupled to the ground terminal. The second bidirectional switch driver is configured to: provide the first voltage difference or the second voltage difference between the third driver output and the third reference terminal responsive to a state of the second driver input; and provide the third voltage difference between the fourth driver output and the fourth reference terminal.

According to certain aspects, a method of controlling a bidirectional switch comprises receiving a bidirectional switch control signal. The method also comprises responsive to the bidirectional switch control signal having a first state, providing a first voltage difference between a first switch control terminal and a first current terminal of a bidirectional switch. The method further comprises responsive to the bidirectional switch control signal having a second state, providing a second voltage difference between the first switch control terminal and the first current terminal of the bidirectional switch. The method further comprises providing a third voltage difference between a second switch control terminal and a second current terminal of the bidirectional switch, a magnitude of the third voltage difference being between respective magnitudes of the first and second voltage differences.

The foregoing summary outlines rather broadly various features of examples of the present disclosure so that the following detailed description may be better understood. Additional features and advantages of such examples will be described hereinafter. This summary is neither intended to identify key or essential features of the claimed subject matters, nor is it intended to be used in isolation to determine the scope of the claimed subject matters. The subject matters should be understood by reference to appropriate portions of the entire specification of this disclosure, any or all drawings, and each claim. The foregoing, together with other features and examples, will be described in more detail below in the following specification, claims, and accompanying drawings.

### BRIEF DESCRIPTION OF THE DRAWINGS

Illustrative examples are described in detail below with reference to the following figures.

FIG. 1 is a schematic of an example of a bidirectional switch.

FIG. 2 is a cross-sectional view of the bidirectional switch of FIG. 1.

FIG. 3 includes graphs that illustrate examples of control signals of the bidirectional switch of FIGS. 1 and 2.

FIG. 4 illustrates an example of operation of the bidirectional switch of FIG. 1 responsive to the control signals illustrated in FIG. 3.

FIG. 5 include graphs that illustrate examples of electrical properties of the bidirectional switches of FIGS. 1 and 2.

FIG. 6 is a schematic of an example of a bidirectional switch driver.

FIGS. 7 and 8 include graphs that illustrate examples of control signals provided by the bidirectional switch driver of FIG. 6.

FIGS. 9, 10, and 11 are schematics that illustrate examples of internal components of the bidirectional switch driver of FIG. 6.

FIG. 12 is a schematic of an example of a system including the bidirectional switches of FIGS. 1 and 2 and the bidirectional switch driver of FIG. 6.

FIG. 13 include graphs that illustrate examples of operations of the system of FIG. 12.

FIGS. 14A, 14B, and 14C include examples of internal components of the bidirectional switch driver of FIG. 12.

FIG. 15 is a flowchart of an example of a method of operating a bidirectional switch.

The drawings and accompanying detailed description are provided for understanding of features of various examples and do not limit the scope of the appended claims. The examples illustrated in the drawings and described in the accompanying detailed description may be readily utilized as a basis for modifying or designing other examples that are within the scope of the appended claims. One skilled in the art will readily recognize from the following description that alternative embodiments of the structures and methods illustrated may be employed without departing from the principles, or benefits touted, of this disclosure. Identical reference numerals may be used, where possible, to designate identical elements that are common among drawings. The figures are drawn to clearly illustrate the relevant elements or features and are not necessarily drawn to scale.

### DETAILED DESCRIPTION

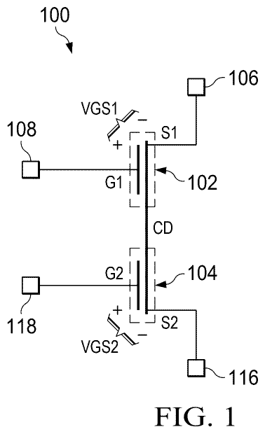

FIG. 1 is a schematic of an example of a bidirectional switch 100. Bidirectional switch 100 includes a switch device 102 and a switch device 104. The switch device 102 includes a current terminal 106 and a switch control terminal 108. The switch device 104 includes a current terminal 116 and a switch control terminal 118. In some examples, switch devices 102 and 104 are gallium nitride (GaN)-based high electron mobility transistors (HEMTs). The two transistors forming the switch devices 102 and 104 can share a common drain (labelled CD), which can be inaccessible (e.g., by an electrode or other metal interconnect) to reduce the current path distance between current terminal 106 and current terminal 116, which can reduce the on-resistance of bidirectional switch 100. In some examples, the switch control terminals 108 and 118 are coupled to, respectively, the gates G1 and G2 of the two transistors forming the switch devices 102 and 104. Also, the current terminals 106 and 116 are coupled to, respectively, the sources S1 and S2 of the two transistors.

Compared to silicon-based transistors, GaN-based HEMTs may have high breakdown field, high electron mobility, low on-state resistance, high current, faster-switching speed, high thermal conductivity, and excellent reverse-recovery performance, and thus may be more suitable for applications where a low-loss and high-efficiency performance may be desired, such as power electronics or radio frequency (RF) circuits. A GaN-based HEMT may allow current to flow from the drain to source and vice versa when the HEMT is turned on (in the ON state), may block the current flow from the drain to source when the HEMT is turned off (in the OFF state), and may have lower static on-state resistance (and thus lower voltage drop and lower power loss) than MOSFETs due to, for example, the high electron mobility. Therefore, GaN-based HEMTs may be suitable for use in bidirectional switches and may offer higher switching speed and lower power loss and voltage drop. In addition, due to the lateral device structure and the nonexistence of body diodes in GaN-based HEMTs, it can be relatively easy to fabricate monolithic bidirectional switches implemented using GaN-based HEMTs.

Bidirectional switch 100 can support bidirectional current flow between current terminals 106 and 108 when both switch devices 102 and 104 are turned on, and can provide bidirectional voltage blocking when at least one of switch devices 102 and 104 is turned off. Bidirectional switch 100 may be used, for example, as a bidirectional power switch for charger multiplexing, where the bidirectional switch may be turned on to charge a battery using a current from a power supply to the battery, or to provide a current from the battery to a load. The bidirectional switch may also be turned off to block current in either direction, for example, to avoid draining a charged battery or prevent one battery from charging another battery.

Another example application of bidirectional switch 100 is in a switch-mode converter, such as an alternating current (AC) to direct current (DC) converter, an AC cycloconverter, etc. In such application, as to be described below, the voltage across the bidirectional switch can be an AC voltage that changes polarity between a positive half cycle and a negative half cycle. For example, in a positive half cycle, the voltage at current terminal 106 can be higher than the voltage at current terminal 116, and in a negative half cycle, the voltage at current terminal 106 can be lower than the voltage at current terminal 116. In such application, bidirectional switch 100 may be turned on to enable a current to flow between current terminals 106 and 116, or to block a current (and/or a voltage) between current terminals 106 and 116, in both the positive and negative half cycles.

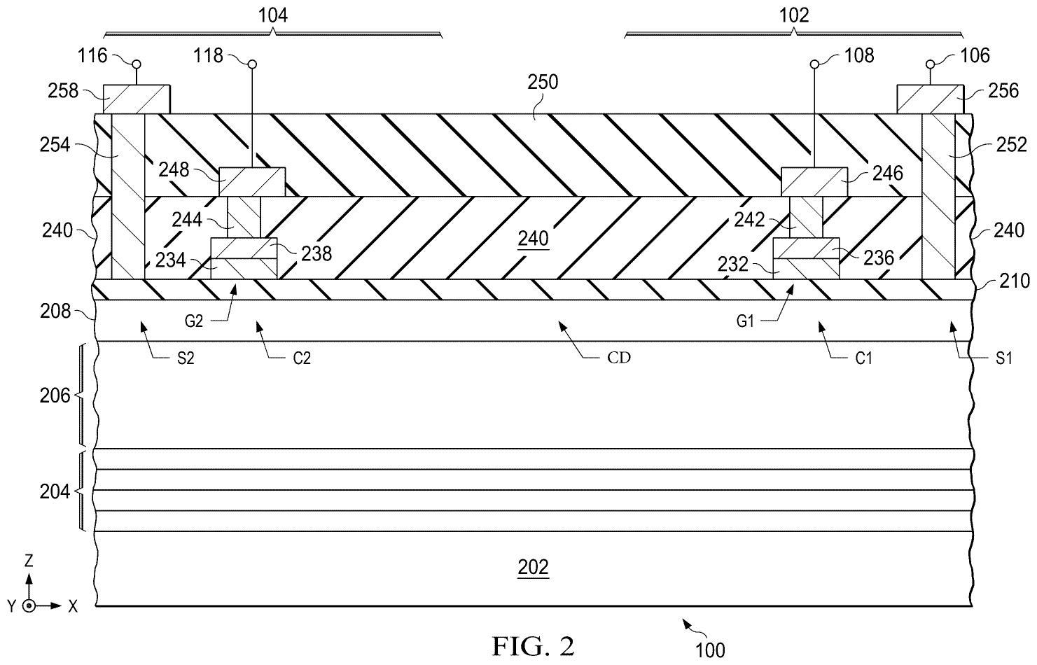

FIG. 2 illustrates an example of a cross section view of bidirectional switch 100. FIG. 2 shows a semiconductor substrate 202, transition layer(s) 204, a conductive barrier structure 206, a channel layer 208, and a barrier layer 210. Examples of these components and their functions are described in, for example, related U.S. application Ser. No. 18/326,698, titled “INTEGRATED DEVICES WITH CONDUCTIVE BARRIER STRUCTURE”, filed on May 31, 2023, and related U.S. application Ser. No. 18/534,056, titled “INTEGRATED DEVICES WITH CONDUCTIVE BARRIER STRUCTURE”, filed on Dec. 8, 2023, the entireties of which are incorporated herein by reference.

Specifically, the semiconductor substrate 202 may be a bulk semiconductor substrate, a semiconductor-on-insulator (SOI) substrate, or any other appropriate substrate. For example, the semiconductor substrate 202 may be or include bulk silicon wafer. The transition layer(s) 204 may include any number of layers that are configured to accommodate lattice mismatch between the semiconductor substrate 202 and the conductive barrier structure 206 (e.g., to reduce or minimize lattice defect generation and/or propagation in the conductive barrier structure 206). For example, the transition layer(s) 204 may have a gradient concentration of one or more elements in a direction normal to the top surface of the semiconductor substrate 202. The semiconductor substrate 202 may be floating, or otherwise disconnected from the source regions S1/S2 of the switch devices 104 and 102, to avoid semiconductor substrate 202 being tied to either one of the source regions S1 or S2 (and current terminals 106 and 116), which can worsen backgating.

Backgating occurs when the substrate voltage of the bidirectional switch experiences a positive or a negative swing relative to source regions S1/S2 as source voltages switch. The substrate voltage may modulate the channel of the switch devices of the bidirectional switch and prevent the switch devices from switching. Hard-tying the substrate (or substrate bias terminal 120) to one of the source regions S1/S2 can further worse the effect of backgating. For example, if the voltage of source region S1 (VS1) is higher than the voltage of source region S2 (VS2), and substrate bias terminal 120 is hard-tied to source region S1 (or current terminal 114), the high VS1 (or a substrate voltage caused by VS1) can modulate the channel of switch device 104 and prevent switch device 104 from turning on. Also, if the voltage of source region S2 (VS2) is higher than the voltage of source region S1 (VS1), and semiconductor substrate 202 is hard-tied to source region S2 (or current terminal 116), the high VS2 (or a substrate voltage caused by VS2) can modulate the channel of switch device 102 and prevent switch device 102 from turning on.

One way to mitigate the effect of backgating is by having semiconductor substrate 202 and substrate bias terminal 120 floating. Such arrangements, however, may still allow voltages at the source regions (e.g., VS1, VS2) to couple into the channel regions (e.g., C1 or C2) via the parasitic capacitance between the source regions and semiconductor substrate 202. Moreover, with semiconductor substrate 202 floating, there may lack a fast discharge path for the charge accumulated in semiconductor substrate 202 due to the source voltage coupling. Accordingly, the substrate charge may remain for an extended period of time, and the substrate bias voltage may still modulate the channel of switch devices 102/104 and prevent the switching of the switch devices.

The conductive barrier structure 206 can further reduce backgating by providing a conductive shield that can further block the voltage at semiconductor substrate 202 from propagating to the channel region of another switch device. The conductive barrier structure 206 includes a confinement layer and a low bandgap energy material layer. For example, the low bandgap energy material layer may be over the semiconductor substrate 202 and the transition layer(s) 204, and the confinement layer may be over and on the low bandgap energy material layer. The conductive barrier structure 206 (e.g., the confinement layer) is configured to conduct and confine charge carriers within two dimensions. In some examples, the charge carriers that the conductive barrier structure 206 is configured to conduct and confine are holes. A confinement layer may be configured to conduct and confine charge carriers based on band energy bending, which may, at least in part, be a function of materials adjoining the confinement layer. The conductive barrier structure 206 is configured to include a two-dimensional hole gas (2DHG), quantum well, or the like in various examples. The confinement layer and a low bandgap energy material layer may be a repeated unit (e.g., repeated two or more times) in the conductive barrier structure 206, which may form a combination of layers that have a series of 2DHGs and/or 2DEGs, a mini-superlattice structure, or a superlattice structure.

In some examples, the conductive barrier structure 206 includes, e.g., as a confinement layer, an aluminum gallium nitride (AlGaN) layer, an aluminum nitride (AlN) layer, aluminum antimony nitride (AlSbN) layer, or aluminum indium nitride (AllInN) layer, and includes, e.g., as a low bandgap energy material layer, a gallium nitride (GaN) layer. In examples in which the conductive barrier structure 206 includes a gallium nitride (GaN) layer, the conductive barrier structure 206 may be referred to as a conductive GaN barrier structure 206. Other materials may be implemented for one or more layers of the conductive barrier structure 206.

In some examples, the material of the conductive barrier structure 206 is or includes intrinsic (e.g., undoped) material. In some examples, material(s) of the conductive barrier structure 206 includes a doped material. In some examples, a confinement layer and a low bandgap energy material layer may be doped with carbon, magnesium, or the like. In some examples, a confinement layer may be doped with magnesium, and a low bandgap energy material layer may be doped with carbon. Other dopants may be implemented in the conductive barrier structure 206. A confinement layer may be doped with a uniform dopant concentration or, as described in detail subsequently, may be doped with a lateral dopant gradient concentration (e.g., having a concentration gradient along the x or y axes), to introduce IR drop and charge depletion.

The channel layer 208 is configured, possibly in conjunction with the barrier layer 210, to conduct and confine charge carriers within two dimensions. In some examples, the charge carriers that the channel layer 208 is configured to conduct and confine are electrons. The channel layer 208 is configured to include a two-dimensional electron gas (2DEG) in various examples. More generally, the channel layer 208 is configured to conduct a charge of a first polarity that is opposite from a second polarity of a charge that the conductive barrier structure 206 is configured to conduct. In some examples, the channel layer 208 includes a gallium nitride (GaN) layer and, in such examples, may be referred to as a GaN channel layer 208 or GaN layer 208. In some examples, the material of the channel layer 208 is or includes an unintentionally doped material, such as a material doped by diffusion of dopants from another layer. The barrier layer 210, in some examples, may be or include an AlGaN layer, or an aluminum nitride (AlN) layer.

A first gate layer 232 is over and on an upper surface of the barrier layer 210, and a second gate layer 234 is over and on an upper surface of the barrier layer 210. A first gate metal layer 236 is over and on the first gate layer 232, and a second gate metal layer 238 is over and on the second gate layer 234. The gate layers may be or include, in some examples, a p-doped gallium nitride (pGaN) layer. The gate metal layers may be or include, in some examples, aluminum nitride (AlN). First gate layer 232 and/or second gate layer 234 can receive a positive voltage, which causes the pGaN layer to inject holes into conductive back barrier structure 206, and set a bias voltage of conductive back barrier structure 206. The injection of holes into conductive back barrier structure 206 can also occur when the gate-source voltage of switch device 102/switch device 104 is zero, and the amount of holes injected increases with the gate-source voltage.

The switch device 102 includes a first source region S1, a first channel region C1, a common drain region CD, and a first gate structure G1. The second switching device 104 includes a second source region S2, a second channel region C2, the common drain region CD, and a second gate structure G2. The first gate structure G1 includes the first gate layer 232 and the first gate barrier layer 236. The first channel region C1 is in the channel layer 208 underlying the first gate structure G1. The first channel region C1 is laterally between the first source region S1 and the common drain region CD, which are also in the channel layer 208. The second gate structure G2 includes the second gate layer 234 and the second gate barrier layer 238. The second channel region C2 is in the channel layer 208 underlying the second gate structure G2. The second channel region C2 is laterally between the second source region S2 and the common drain region CD, which are also in the channel layer 208. The common drain region CD is laterally between (i) the first gate structure G1 and first channel region C1 and (ii) the second gate structure G2 and second channel region C2. The first source region S1, first gate structure G1, common drain region CD, second source region S2, and second gate structure G2 correspond to the first source terminal S1, first gate terminal G1, common drain CD, second source terminal S2, and second gate terminal G2, respectively, of FIG. 2.

A first dielectric layer 240 is over and on the barrier layer 210 and gate barrier layers 236, 238 and along sidewalls of the gate layers 232, 234 and gate barrier layers 236, 238. A first gate electrical contact 242 extends through the first dielectric layer 240 and contacts the first gate barrier layer 236, and a second gate electrical contact 244 extends through the first dielectric layer 240 and contacts the second gate barrier layer 238. A metal line 246 in a first metal layer is over and on the first gate electrical contact 242 and an upper surface of the first dielectric layer 240, and a metal line 248 in the first metal layer is over and on the second gate electrical contact 244 and the upper surface of the first dielectric layer 240.

In a case where bidirectional switch 100 includes enhancement mode (E-mode) HEMTs, first gate layer 234, first gate metal layer 238, and first gate electrical contact 244 form a Schottky contact, or an ohmic contact, with an underlying layer(s), and the second gate layer 232, second gate metal layer 236, and second gate electrical contact 242 form a Schottky contact, or an ohmic contact, with an underlying layer(s). In some examples, as described above, first gate electrical contact 242 and second gate electrical contact 244 can be electrically coupled together (e.g., through metal lines 246 and 248) to form a single gate/switch control terminal.

A second dielectric layer 250 is over and on the first dielectric layer 240 and the metal lines 256, 258. A first source electrical contact 252 extends through the second dielectric layer 250 and first dielectric layer 240 and contacts the barrier layer 210 on the first source region S1. A second source electrical contact 254 extends through the second dielectric layer 250 and first dielectric layer 240 and contacts the barrier layer 210 on the second source region S2. Metal lines 256, 258 in a second metal layer are over and on the source electrical contacts 252, 254, respectively, and an upper surface of the second dielectric layer 250.

Additional dielectric layers and metal layers may be formed on and over the second dielectric layer 250. The first dielectric layer 240, additional dielectric layers, first metal layer, second metal layer, and additional metal layers may form an interconnect structure. Metal lines in neighboring metal layers may be electrically coupled by metal vias.

The metal line 256 is electrically coupled to the current terminal 106 of bidirectional switch 100. The metal line 258 is electrically coupled to the current terminal 116 of bidirectional switch 110 through the interconnect structure. The metal line 246 is electrically coupled to the first control terminal 108 of bidirectional switch 100 through the interconnect structure. The metal line 248 is electrically coupled to the second control terminal 118 of bidirectional switch 100 through the interconnect structure.

In the examples of FIGS. 1 and 2, the HEMTs of switch devices 102 and 104 are enhancement mode devices. The pGaN gate layers 232 and 234 can deplete electrons in the 2DEG channel under the respective gate structures G1 and G2, and switch devices 102 and 104 are disabled when no gate drive voltage is applied to the gate electrical contacts 242 and 244. To turn on a switch device, a positive voltage difference can be applied between the gate and source of the switch device. If the positive voltage difference exceeds a threshold voltage (e.g., of the Schottky contact), the gate structure can attract electrons to replete the 2DEG and form a channel under the gate structure, thereby turning on the HEMT and the switch device. For example, switch device 102 can be turned on if a voltage difference between the switch control terminal 108 and the current terminal 106 (coupled to gate G1 and source S1 respectively), VGS1, exceeds a threshold. Also, switch device 104 can be turned on if a voltage difference between the switch control terminal 118 and the current terminal 116 (coupled to gate G2 and source S2 respectively), VGS2, exceeds a threshold.

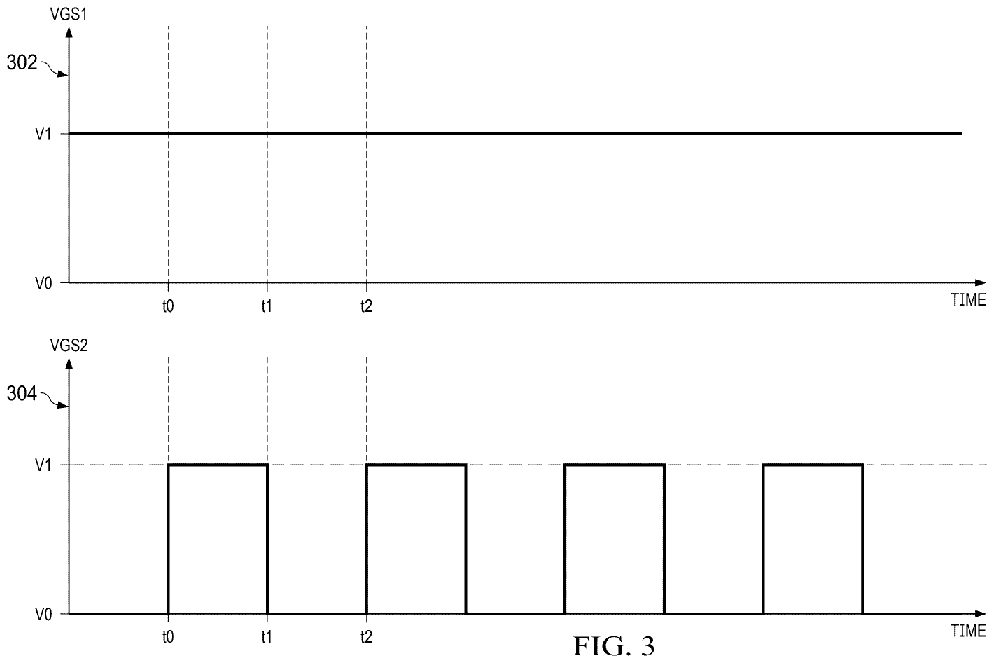

FIG. 3 includes graphs that illustrate examples of gate-source voltages of bidirectional switch 100. FIG. 3 includes graphs 302 and 304. Graph 302 illustrates an example variation of gate-source voltage of switch device 102 (VGS1) with respect to time. Graph 304 illustrates an example variation of gate-source voltage of switch device 104 (VGS2) with respect to time. The gate-source voltages shown in FIG. 3 can be caused by control signals provided by a driver circuit to bidirectional switch 100 under an operation condition where current terminal 106 of bidirectional switch 100 receives a higher voltage than current terminal 116, and switch device 102 can operate as a high side switch and switch device 104 can operate as a low side switch.

Referring to graph 304, a switching control signal can be provided to switch device 104 so that the gate-source voltage VGS2 of switch device 104, provided by the voltage difference between switch control terminal 104 and current terminal 116, switches between a low voltage V0 and a high voltage V1. In some examples, the low voltage V0 can be 0V, and the high voltage V1 can be 6V or higher. With VGS2 at 0V, the channel of switch device 104 can be depleted, and the low VGS2 may be designed to turn off switch device 104. The high voltage V1 can be a maximum voltage tolerated by the devices of the driver circuit, a supply voltage provided to the driver circuit, etc. With VGS2 at V1, the channel of switch device 104 can be formed to conduct a current, and switch device 104 is turned on.

Also, referring to graph 302, a static control signal can be provided to switch device 102 so that the gate-source voltage VGS1 stays at the high voltage V1, and switch device 102 remains in the on state while switch device 104 switches between the on state and the off state. The state of bidirectional switch 100 can follow the state of switch device 104. For example, between times t0 and t1 when both VGS1 and VGS2 are at the high voltage V1, both switch device 102 and switch device 104 are in the on state, and bidirectional switch 100 can also be in the on state and allow current to flow from current terminal 106 to current terminal 116. Also, between times t1 and t2, VGS1 is at the high voltage V1 and VGS2 is at the low voltage V0. Switch device 102 is in the on state, while switch device 104 is in the off state. Because switch devices 102 and 104 are in series, bidirectional switch 100 can be in the off state, where switch device 104 can block current from reaching current terminal 116.

Maintaining VGS1 at the high voltage V1, while switching VGS2 between the high voltage V1 and the low voltage V0, can provide various advantages. Specifically, because VGS1 is not switched (or at least switched much less frequent than VGS2), the power loss associated with the switching of VGS1 can be eliminated or at least reduced. Maintaining VGS1 at the high voltage V1 can also reduce the on-state resistance of bidirectional switch 100 between current terminals 106 and 116 (e.g., between t0 and t1). All these can improve the power efficiency of a system including bidirectional switch 100. Meanwhile, although switch device 102 remains in the on state, bidirectional switch 100 can still be switched off, and the current path between current terminals 106 and 116 can be disabled, when switch device 104 is switched off (e.g., between t1 and t2).

The control signals scheme in FIG. 3, however, may create a leakage current path through the conductive barrier structure 206, which can lead to a substantial leakage current flowing between current terminals 106 and 116 when switch device 104 is to be switched off and bidirectional switch 100 is to be in the off state. The substantial off-state leakage current can lead to substantial power dissipation at bidirectional switch 100, especially when a large voltage (e.g., 600 V) is applied across bidirectional switch 100.

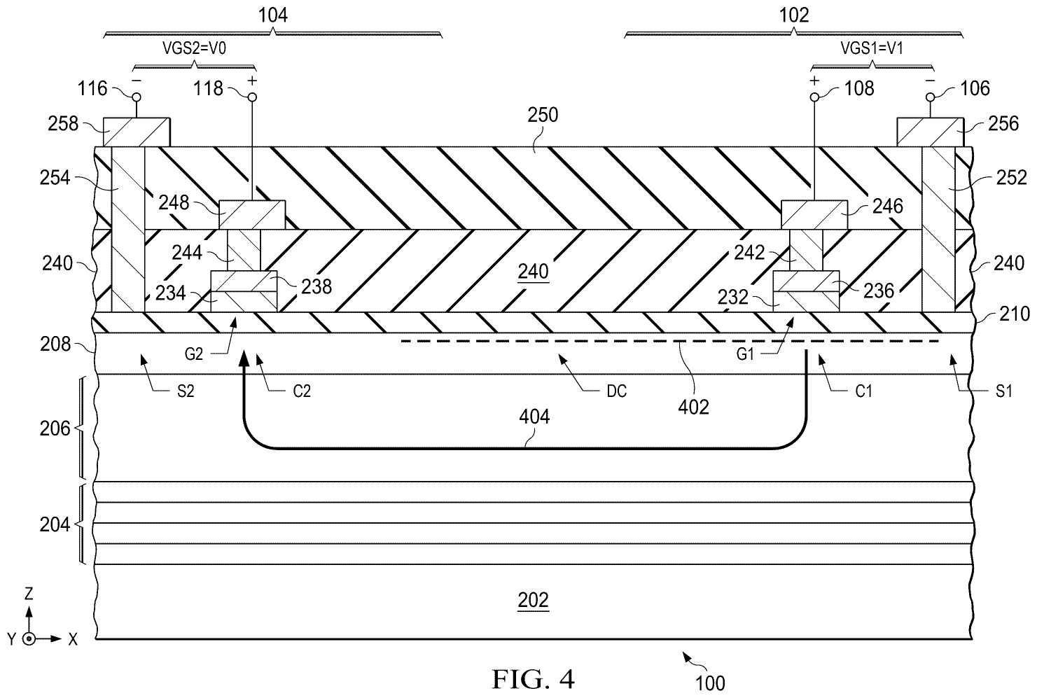

FIG. 4 illustrates an example of operation of bidirectional switch 100 responsive to the gate-source voltages of switch devices 102 and 104 shown in FIG. 3. Referring to FIG. 4, with the control signals shown in FIG. 3, VGS1 of switch device 102, between switch control terminal 108 and current terminal 106, is at the high voltage V1, and VGS2 of second switch 104, between switch control terminal 118 and current terminal 116, is at the low voltage V0. Accordingly, a channel 402 is in channel region C1 of switch device 102, while no channel is formed in channel region C2 of switch device 104 as the charge is depleted by the pGaN second gate layer 234.

Also, as described above, pGaN first gate layer 232 can inject hole charge into conductive barrier structure 206. Due to the high voltage at switch control terminal 108, pGaN first gate layer 232 can inject a substantial amount of hole charge into conductive barrier structure 206. The hole charge can flow along a current path 404 from channel region C1 to channel region C2 and current terminal 116, which leads to a substantial off-state leakage current. The amount of hole charge injected by pGaN first gate layer 232, as well as the amount of the off-state leakage current, can increase with the VGS1 voltage.

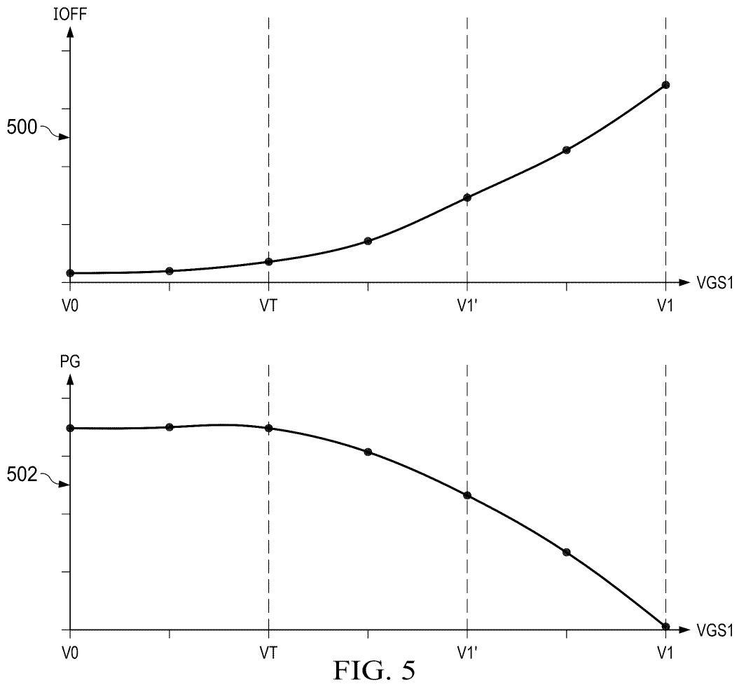

FIG. 5 includes graphs that illustrate examples of electrical properties of bidirectional switch 100. FIG. 5 includes graphs 500 and 502. Graph 500 illustrates an example variation of off-state leakage current (IOFF) of bidirectional switch 100 with respect to the VGS1 voltage, when VGS2 is zero and switch device 104 is in the off state, and bidirectional switch 100 is also to be in the off state. Graph 502 illustrates an example variation of the gate power loss (PG) of bidirectional switch 100 with respect to the lower toggling voltage of VGS1. In graph 502, VGS1 at V0 indicates that VGS1 toggles between V0 and V1, whereas VGS1 at V1 indicates that VGS1 stays at V1.

Referring to graph 500, with VGS1 at a value between V0 and VT, which represents a threshold voltage of switch device 102, switch device 102 is off, and the amount of hole charge injected by the pGAN gate layer 232 of switch device 102 into conductive back barrier 206 is relatively small and increases approximately linearly with VGS1. IOFF is also relatively low and increases approximately linearly with VGS1. With VGS1 above VT, switch device 102 is on, and the amount of hole charge injected by the pGAN gate layer 232, as well as IOFF, increases quadratically with VGS1. Accordingly, with VGS1 at V1, the IOFF can be several times higher than at a low VGS1, such as at V1′.

Also, referring to graph 502, with VGS1 staying at V1, PG can be at a minimum because switch device 102 is not switched, and therefore no power is lost in switching the gate of switch device 102. As the swing of VGS1 increases by decreasing the lower toggling voltage of VGS1, PG increases, and PG can increase approximately quadratically with the swing of VGS1. PG can reach maximum when VGS1 toggles between VT and V1. As the lower toggling voltage of VGS1 further decreases below VT, PG does not further increase at least because switch device 102 is off and further gate-charge change is marginal.

Graphs 500 and 502 illustrate that IOFF increases with VGS1, while PG decreases with the lower toggling voltage of VGS1. Accordingly, VGS1 can be configured or programmed based on a tradeoff between IOFF and PG. For example, for applications in which bidirectional switch 100 is switched at a relatively low frequency, PG can be relatively low. Therefore the lower toggling voltage of VGS1 can be set closer to VT to reduce IOFF. Also, for applications in which bidirectional switch 100 is switched at a relatively high frequency, PG can be relatively high. Therefore the lower toggling voltage of VGS1 can be set closer to V1, or VGS1 can be set at a static voltage closer to V1, to reduce PG.

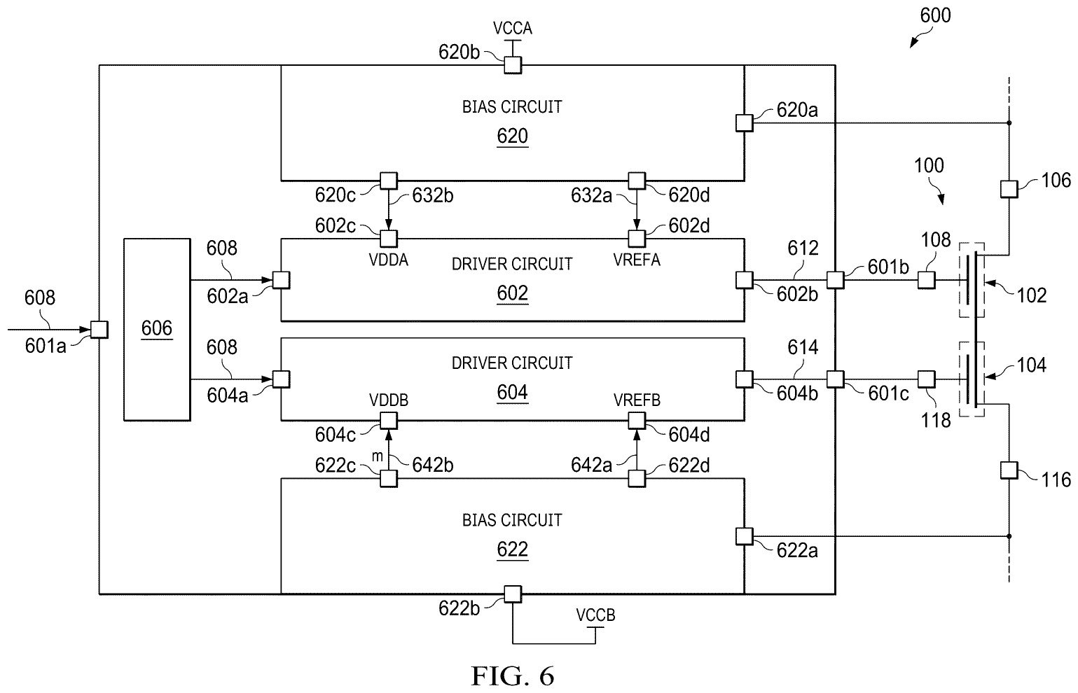

FIG. 6 illustrates an example of a bidirectional switch driver 600 that can address at least some of the issues described above. As shown in FIG. 6, bidirectional switch driver 600 has a switch control input 601a, a switch control output 601b, and a switch control output 601c. Bidirectional switch driver 600 also includes a driver circuit 602 and a driver circuit 604. Driver circuit 602 has an input 602a, an output 602b, a power supply terminal 602c (also labelled VDDA), and a reference terminal 602d (also labelled VREFA). Driver circuit 604 has an input 604a, an output 604b, a power supply terminal 604c (also labelled VDDB), and a reference terminal 604d (also labelled VREFB). Output 602b of driver circuit 602 is coupled to switch control terminal 108 via switch control output 601b. Output 604b of driver circuit 604 is coupled to switch control terminal 108 via switch control output 601c. Input 602a of driver circuit 602 and input 604a of driver circuit 604 are coupled to switch control input 601a via an input circuit 606. Input circuit 606 can receive a switching driver control signal 608 which can set the on/off state of bidirectional switch 100. In some examples, input circuit 606 include buffers to forward driver control signal 608 to each of inputs 602a and 604a, as shown in FIG. 6. In some examples, as to be described below, input circuit 606 can forward driver control signal 608 to one of inputs 602a/604b, and provide a different control signal to another one of inputs 602a/604b. Responsive to driver control signal 608 and/or other driver control signal provided by input circuit 606, driver circuit 602 can provide a drive signal 612, and driver circuit 604 can provide a drive signal 614.

In some examples, bidirectional switch driver 600 and bidirectional switch 100 are integrated within a single integrated circuit and can be of different dies having different transistor devices. For example, bidirectional switch driver 600 can include silicon-based transistors such as metal-oxide-semiconductor field-effect transistor (MOSFETs), and bidirectional switch 100 can include HEMTs. In some examples, bidirectional switch driver 600 and bidirectional switch 100 can be integrated on the same die, where both bidirectional switch driver 600 and bidirectional switch 100 include HEMTs.

Driver circuits 602 and 604 are configured to provide, respectively, drive signals 612 and 614 having different voltage swings at outputs 602b and 604b. For example, in a case where current terminal 106 has a higher voltage than current terminal 116, switch device 102 operates as a high side switch and switch device 104 operates as a low side switch, drive signal 612 can have a reduced voltage swing than drive signal 614. Also, in a case where current terminal 116 has a higher voltage than current terminal 106, switch device 104 operates as a high side switch and switch device 102 operates as a low side switch, drive signal 614 can have a reduced voltage swing than drive signal 612.

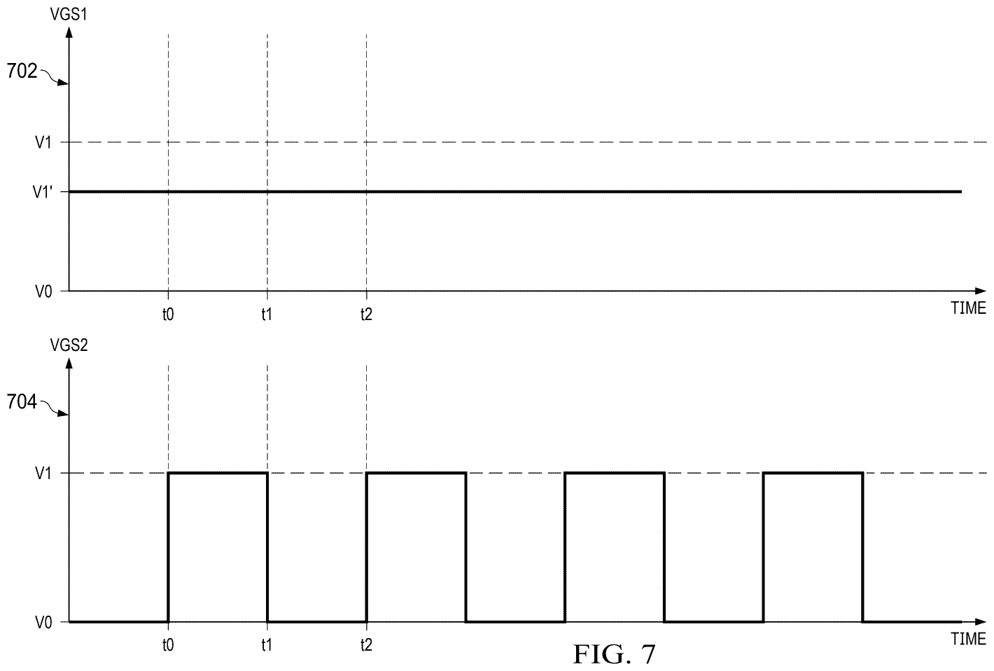

FIG. 7 includes graphs that illustrate examples of gate-source voltages of bidirectional switch 100 caused by drive signals 612 and 614. FIG. 7 includes graphs 702 and 704. Graph 702 illustrates an example variation of gate-source voltage of switch device 102 (VGS1) with respect to time. Graph 704 illustrates an example variation of gate-source voltage of switch device 104 (VGS2) with respect to time.

Referring to graph 704, driver circuit 604 can provide a switching drive signal 614 to switch device 104 responsive to the switching driver control signal 608, so that the gate-source voltage VGS2 of switch device 104 switches between V0 and V1, as in FIG. 3. Also, referring to graph 702, driver circuit 602 can provide a static drive signal 612 to switch device 102 so that the gate-source voltage VGS1 stays at voltage V1′, which is between V0 and V1 and is high enough to turn on switch device 102. For example, in a case where V0 is 0V and V1 is 6V, V1′ can be at 4V. But with V1′ lower than V1, the amount of hole charge injected by pGAN gate layer 232, as well as the off-state leakage current through bidirectional switch 100, can be reduced. Also, because switch device 102 is not switched, the gate power loss (PG) can be minimized or at least reduced. The state of bidirectional switch 100 can follow the state of switch device 104. For example, between times t0 and t1 when VGS1 is at V1′ and VGS2 is at V1, both switch device 102 and switch device 104 are in the on state, and bidirectional switch 100 can also be in the on state and allow current to flow from current terminal 106 to current terminal 116. Also, between times t1 and t2, VGS1 is at V1′ and VGS2 is at V0. Switch device 102 is in the on state, while switch device 104 is in the off state. Because switch devices 102 and 104 are in series, bidirectional switch 100 can be in the off state, where switch device 104 can block current from reaching current terminal 116, and the off-state leakage current of bidirectional switch 100 can also be reduced due to the reduced VGS1 when bidirectional switch 100 is in the off state.

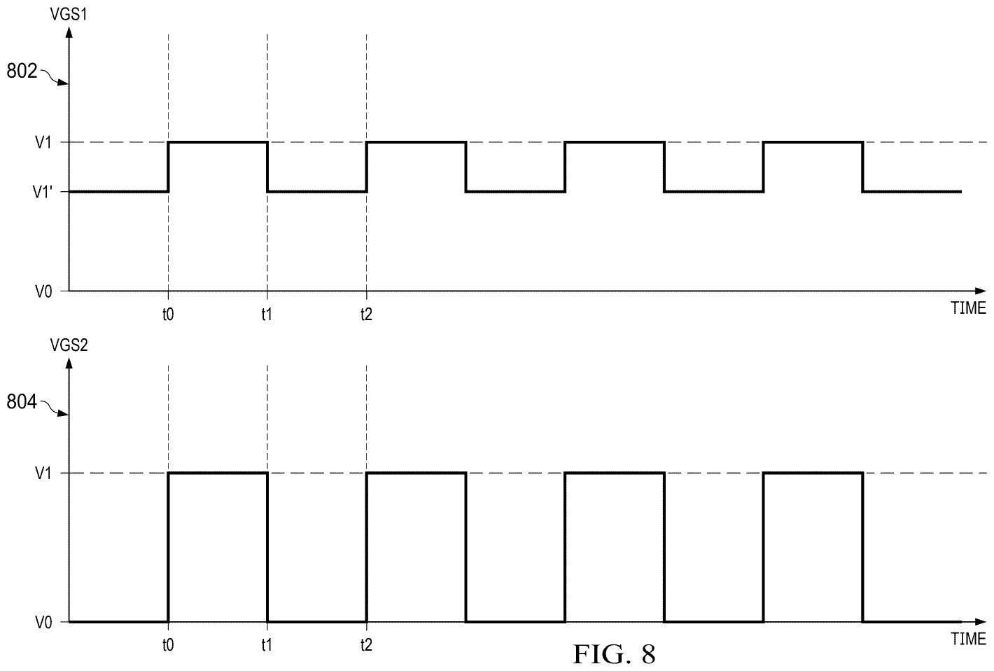

FIG. 8 includes graphs that illustrate additional examples of gate-source voltages of bidirectional switch 100 caused by drive signals 612 and 614. FIG. 8 includes graphs 802 and 804. Graph 802 illustrates an example variation of gate-source voltage of switch device 102 (VGS1) with respect to time. Graph 804 illustrates an example variation of gate-source voltage of switch device 104 (VGS2) with respect to time.

Referring to graph 804, driver circuit 604 can provide a switching drive signal 614 responsive to the switching driver control signal 608 to switch device 104 so that the gate-source voltage VGS2 of switch device 104 switches between V0 and V1, as in FIGS. 3 and 7. Also, referring to graph 802, driver circuit 602 can provide a switching drive signal 612 so that the gate-source voltage VGS1 switch between voltage V0 and V1′. The switching of the gate-source voltage VGS1 can be synchronous with the switching of the gate-source voltage VGS2. For example, between t0 and t1, both VGS1 and VGS2 are at V1 so that both switch devices 102 and 104 are fully switched on, and bidirectional switch 100 is also in the on state. Between t1 and t2, VGS1 is at V1′ so that switch device 102 is in the on, while VGS2 is at V0 so that switch device 104 is off, and bidirectional switch 100 is in the off state, and the off-state leakage current of bidirectional switch 100 can also be reduced due to the reduced VGS1. The control signals arrangements in FIG. 8 can reduce the on-state resistance of bidirectional switch 100 while incurred additional PG due to the switching of the gate-source voltage VGS1, while the off-state leakage current of bidirectional switch 100 can be reduced due to the reduced VGS1 when bidirectional switch 100 is in the off state.

In some examples, driver circuits 602 and 604 can receive different bias voltages at the respective power supply terminals (e.g., VDDA/VDDB) and/or the respective reference terminals (e.g., VREFA/VREFB), which causes/configures driver circuits 602 and 604 to provide drive signals 612 and 614 having different voltage swings at outputs 602b and 604b. For example, driver circuit 602 can provide a switching drive signal 612 having a voltage swing between the VDDA voltage and the VREFA voltage to toggle VGS1 between V0 and V1′, or provide a static drive signal at the VREFA voltage to set VGS1 at V1′. Also, driver circuit 604 can provide a switching drive signal 614 having a voltage swing between the VDDB voltage and the VREFB voltage to toggle VGS1 between V0 and V1. The configurations of the VDDA, VDDB, VREFA, and/or VREFB voltages allow driver circuits 602 and 604 to provide drive signals 612 and 614 having different voltage swings.

Specifically, referring back to FIG. 6, driver circuit 600 can include bias circuits 620 and 622. Bias circuit 620 has a sense input 620a coupled to current terminal 106 via a kelvin connection (not shown), a power supply input 620b coupled to a power supply VCCA, a power supply output 620c coupled to power supply terminal 602c of driver circuit 602, and a reference output 620d coupled to reference terminal 602d of driver circuit 602. Also, bias circuit 622 has a sense input 622a coupled to current terminal 116 via a kelvin connection (not shown), a power supply input 622b coupled to a power supply VCCB, which can be the same or separate from VCCA, a power supply output 622c coupled to power supply terminal 604c of driver circuit 604, and a reference output 622d coupled to reference terminal 604d of driver circuit 604.

Bias circuit 602 can sense the voltage at current terminal 106 via terminal 620a, and provide the VREFA voltage (also labelled 632a) at reference output 620d and the VDDA voltage (also labelled 632b) at power supply output 620c. Also, bias circuit 622 can sense the voltage at current terminal 116 via terminal 622a, and provide the VREFB voltage (also labelled 642a) at reference output 622d and the VDDB voltage (also labelled 642b) at power supply output 622c. In some examples, bias circuit 602 can include a bootstrap circuit to generate the VDDA voltage by adding the VCCA voltage to the VREFA voltage, and bias circuit 624 can include a bootstrap circuit to generate the VDDB voltage by adding the VCCB voltage to the VREFB voltage. In some examples, bias circuits 622 and 624 can also introduce offsets in one or more of the VREFA, VREFB, VDDA, and VDDB voltages, to configure driver circuits 602 and 604 to provide drive signals 612 and 614 having different voltage swings at outputs 602b and 604b. In some examples, bias circuits 622 and 624 allow the offsets to be adjustable via, for example, changing the supply voltages VCCA/VCCB, changing a component of the bias circuit that generates the offset, a bias setting code, etc.

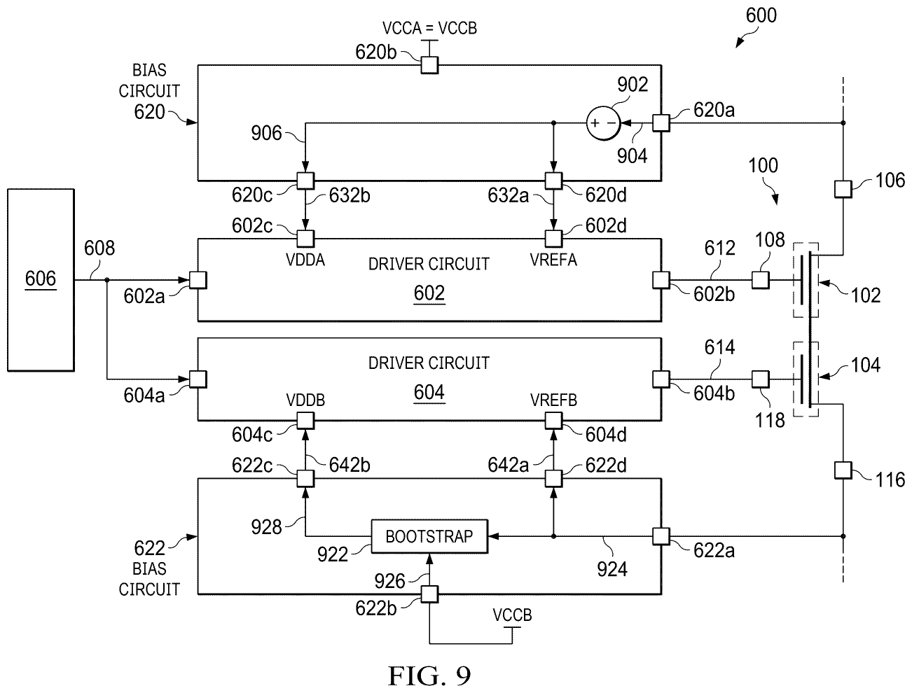

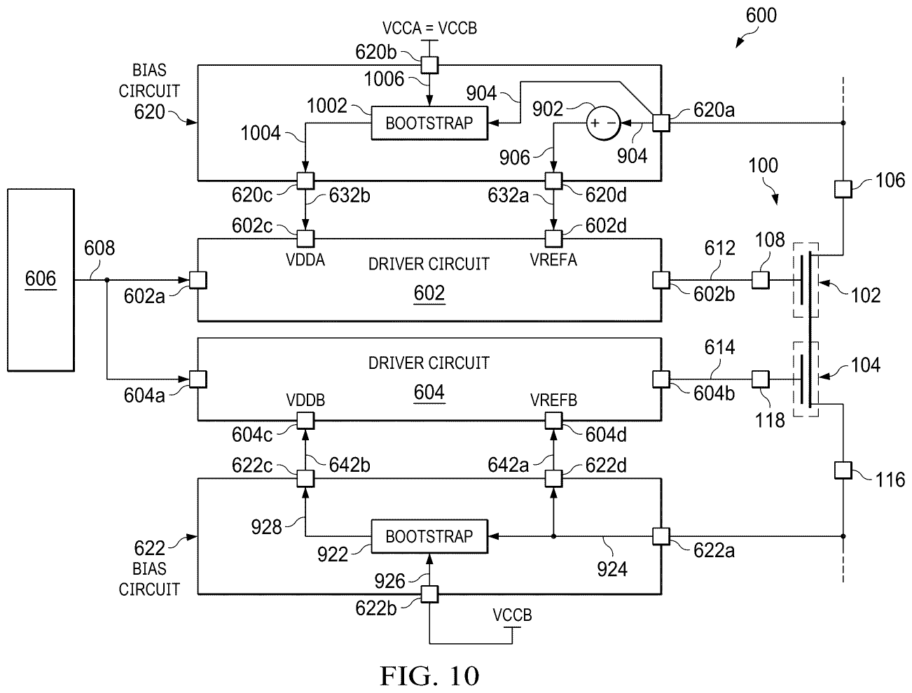

FIGS. 9, 10, and 11 illustrate different examples of bias circuits 620 and 622. In the examples of FIGS. 9 and 10, input circuit 606 can provide driver control signal 608 to both inputs 602a and 604a. Referring to FIG. 9, bias circuit 620 can include a voltage offset circuit 902 coupled between sense input 620a and power supply output 620c and reference output 620d. Voltage offset circuit 902 is configured to generate a voltage 906 by introducing a voltage offset to the sensed voltage 904 voltage at current terminal 106 (sensed via a kelvin connection), and providing voltage 906 as VREFA and VDDA. In some examples, that voltage offset equals to V1′ in FIG. 7. Accordingly, bias circuit 620 can provide a same voltage for VREFA and VDDA by introducing a voltage offset of V1′ to the sensed voltage 904 at current terminal 106, so that driver circuit 602 can provide a static drive signal 612 that sets VGS1 of switch device 108 at V1′ as shown in FIG. 7. Voltage offset circuit 902 can include, for example, a Zener diode, or a programmable digital-to-analog converter DAC, etc. In a case where voltage offset circuit 902 includes a Zener diode, the breakdown voltage of the Zener diode can set the voltage offset, and the voltage offset can be adjusted by swapping out the Zener diode with another Zener diode of different breakdown voltages. In a case where voltage offset circuit 902 includes a DAC, the offset can be adjusted by the changing the digital input to the DAC.

On the other hand, bias circuit 622 provides VREFB as the sensed voltage 924 of current terminal 116. Bias circuit 22 also includes a bootstrap circuit 922 that generates a voltage 928 by adding the VCCB voltage (also labelled 926) to the sensed voltage 924 of current terminal 116, and provide voltage 928 as the VDDB voltage. In such examples, driver circuit 604 can provide a low voltage equal to the VREFB voltage and a high voltage equal to the sum of voltages VREFB+VCCB, and the voltage swing of VGS2 of switch device 118 can be between V0 (0V) and V1 (VCCB), where the voltages of VCCB and VCCA can be equal at V1.

Referring to FIG. 10, bias circuit 620 can include, in addition to voltage offset circuit 902, a bootstrap circuit 1002. Voltage offset circuit 902 is coupled between sense input 620a and reference output 620d, and voltage offset circuit 902 can generate voltage 906 by introducing a voltage offset to the sensed voltage 904 voltage at current terminal 106 (sensed via a kelvin connection), and provide voltage 906 as the VREFA voltage. Also, bootstrap circuit 1002 generates a voltage 1004 by adding the VCCA voltage (also labelled 1006) to the sensed voltage 904 of current terminal 106. Accordingly, bias circuit 620 can provide the VREFA voltage by introducing a voltage offset of V1′ to the sensed voltage 904 at current terminal 106, and provide the VDDA voltage by adding the VCCB voltage to the sensed voltage 904. Accordingly, driver circuit 602 can provide a low voltage equal to the VREFA+V1′ voltage and a high voltage equal to the sum of voltages VREFA+VCCA, and the voltage swing of VGS1 of switch device 108 can be between V1′ and V1 (VCCA), as shown in FIG. 8. Bias circuit 622 in FIG. 10 can be the same as in FIG. 9, and driver circuit 604 can provide a low voltage equal to the VREFB voltage and a high voltage equal to the sum of voltages VREFB+VCCB, and the voltage swing of VGS2 of switch device 118 can be between V0 (0V) and V1 (VCCB), where the voltages of VCCB and VCCA can be equal at V1.

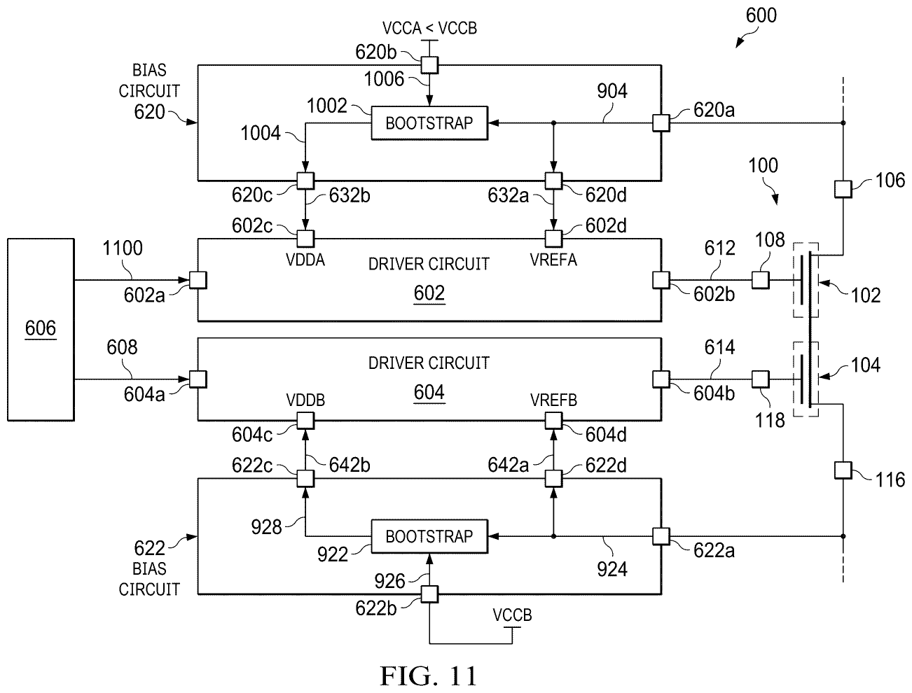

Also, referring to FIG. 11, in some examples, bias circuit 620 can provide the sensed voltage 904 as the VREFA voltage and provide the VDDA voltage as a sum of voltages VREFA+VCCA, and bias circuit 622 can provide the sensed voltage 924 at current terminal 116 as VREFB voltage and provide the VDDB voltage as a sum of voltages VREFB+VCCB. In such examples, the VCCA voltage can be at V1′, while the VCCB voltage can be at V1, and the VCCA voltage is lower than the VCCB voltage. In FIG. 11, input circuit 606 can provide a static driver control signal 1100 to input 602a and the switching driver control signal 608 to input 604a. The static driver control signal 1100 causes driver circuit 602 to provide a static drive signal 612 that sets VGS1 of switch device 108 at V1′.

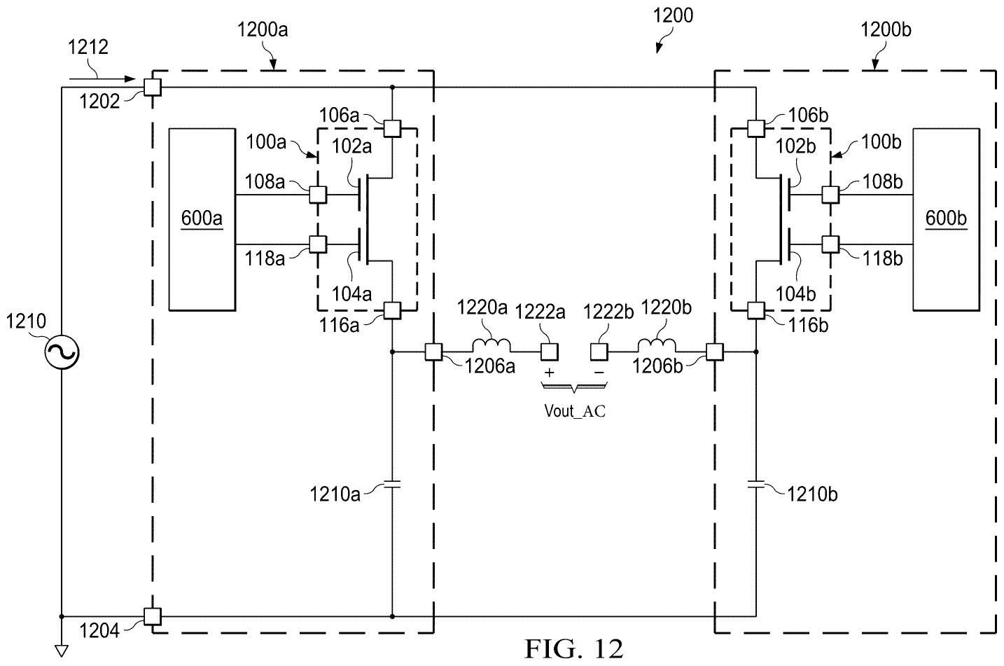

As described above, bidirectional switch 100 can be used as part of a power converter, where the voltage across current terminals 106 and 116 of bidirectional switch 100 switches polarity. FIG. 12 illustrates an example of an AC cycloconverter 1200 including bidirectional switches 100. Referring to FIG. 12, AC cycloconverter 1200 has an AC terminal 1202, an AC terminal 1204, and a pair of switching terminals 1206a and 1206b. AC cycloconverter 1200 includes circuits 1202a and 1202b. Circuit 1202a includes a bidirectional switch 100a and a capacitor 1210a, and circuit 1202b includes a bidirectional switch 100b and a capacitor 1210b. Each of bidirectional switch 100a and bidirectional switch 100b can be an example of bidirectional switch 100 of FIG. 1. Bidirectional switch 100a includes switch devices 102a and 104b and has a current terminal 106a coupled to AC terminal 1202 and a current terminal 116a coupled to switching terminal 1206a, and capacitor 1210a is coupled between switching terminal 1206a and AC terminal 1204. Bidirectional switch 100b includes switch devices 102b and 104b and has a current terminal 106b coupled to AC terminal 1202 and a current terminal 116b coupled to switching terminal 1206b, and capacitor 1210b is coupled between switching terminal 1206b and AC terminal 1204. In some examples, capacitors 1210a and 1210b can be replaced by bidirectional switches 100.

AC cycloconverter 1200 also includes a bidirectional switch driver 600a and a bidirectional switch driver 600b. Bidirectional switch driver 600a is coupled to switch control terminals 108a and 118a of bidirectional switch 100a, and bidirectional switch driver 600b is coupled to switch control terminals 108a and 118a. Bidirectional switch drivers 600a and 600b can include examples of bidirectional switch driver 600 of FIGS. 9-11.

Also, AC terminals 1202 can be coupled to an AC source 1210, which supplies an AC current 1212, and AC terminal 1204 can be coupled to ground. In some examples, AC source 1210 can include a resonant tank current source connected to a direct current (DC) source (e.g., a solar cell, a battery, a DC power source, etc.). Switching terminal 1206a can be coupled via an inductor 1220a to an AC output 1222a, and switching terminal 1206b can be coupled via an inductor 1220b to an AC output 1222b.

Through the switching of bidirectional switches 100a and 100b, AC cycloconverter 1200 can provide an AC voltage (Vout_AC) across AC outputs 1222a and 1222b. During a first half cycle of AC current 1212, bidirectional switch driver 600a can maintain switch device 102a in the on-state, and toggle switch device 104a between on-state and off-state. Also, bidirectional switch driver 600b can toggle switch device 102b between on-state and off-state, and maintain switch device 104b in the on-state. Accordingly, during the first half cycle of AC current 1212, bidirectional switch driver 600a can set the voltage difference between control terminal 108a and current terminal 106a at V1′ (as shown in FIG. 7) or toggle between V1′ and V1 (as shown in FIG. 8). Bidirectional switch driver 600a can also set the voltage difference between control terminal 118a and current terminal 116a to toggle between V0 and V1. Also, bidirectional switch driver 600b can set the voltage difference between control terminal 108b and current terminal 106b to toggle between V0 and V1, and set the voltage difference between the control terminal 118b and current terminal 116b at V1′ or toggle between V1′ and V1.

Also, during the positive half cycle of AC current 1212, bidirectional switch driver 600a can maintain switch device 104a in the on-state, and toggle switch device 102a between on-state and off-state. Also, bidirectional switch driver 600b can toggle switch device 104b between on-state and off-state, and maintain switch device 102b in the on-state. Accordingly, during the positive half cycle of AC current 1212, bidirectional switch driver 600a can set the voltage difference between control terminal 118a and current terminal 116a at V1′ or toggle between V1′ and V1. Bidirectional switch driver 600a can also set the voltage difference between control terminal 108a and current terminal 106a to toggle between V0 and V1. Also, bidirectional switch driver 600b can set the voltage difference between control terminal 118b and current terminal 116b to toggle between V0 and V1, and set the voltage difference between the control terminal 108b and current terminal 106b at V1′ or toggle between V1′ and V1.

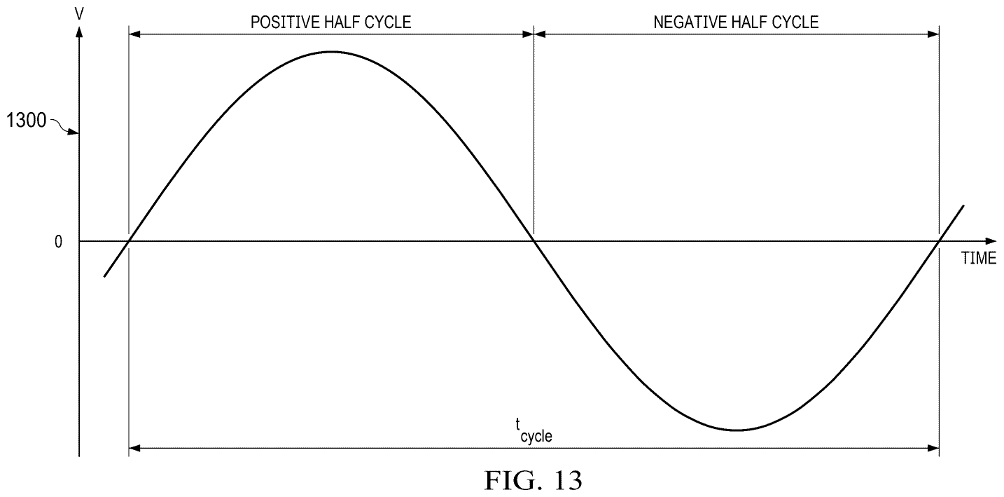

FIG. 13 includes a graph 1302 that illustrates an example of a voltage difference between AC terminal 1202 and AC output 1222a. The voltage difference can be a sinusoidal voltage having a cycle period of t_{cycle}, as shown in FIG. 13. In other examples, the voltage difference can be a square wave, a triangular wave, etc. The voltage difference can have a half cycle where the voltage difference is positive (e.g., exceeding the ground voltage), and a half cycle where the voltage difference is negative (e.g., below the ground voltage). Within the positive half cycle, current terminal 106a has a higher voltage than current terminal 116a, and current terminal 106b has a higher voltage than current terminal 116b. Accordingly, switch device 102 of bidirectional switch 100a/b operates as a high side switch and switch device 104 of bidirectional switch 100a/b operates as a low side switch. Also, within the negative half cycle, current terminal 116a has a higher voltage than current terminal 106a, and current terminal 116b has a higher voltage than current terminal 106b. Accordingly, switch device 104 of bidirectional switch 100a/b operates as a high side switch and switch device 102 of bidirectional switch 100a/b operates as a low side switch.

Each of bidirectional switch drivers 600a and 600b can include a switch network coupled between bias circuits 620/622 and driver circuits 602/604 to provide a drive signal having reduced voltage swing (e.g., to provide a static VGS at V1′ or a switching VGS between V1 and V1′) to the top side switch, and to provide a drive signal having the default voltage swing (e.g., to provide a switching VGS between V0 and V1). The switch can be controlled by a crossover detection signal indicating whether the voltage difference is positive or negative. If the voltage difference between current terminals 106 and 116 is positive and switch device 102 operates as the high side switch, driver circuit 602 can provide drive signal 612 having the reduced voltage swing. If the voltage difference is negative and switch device 104 operates the high side switch, driver circuit 604 can provide drive signal 614 having the reduced voltage swing.

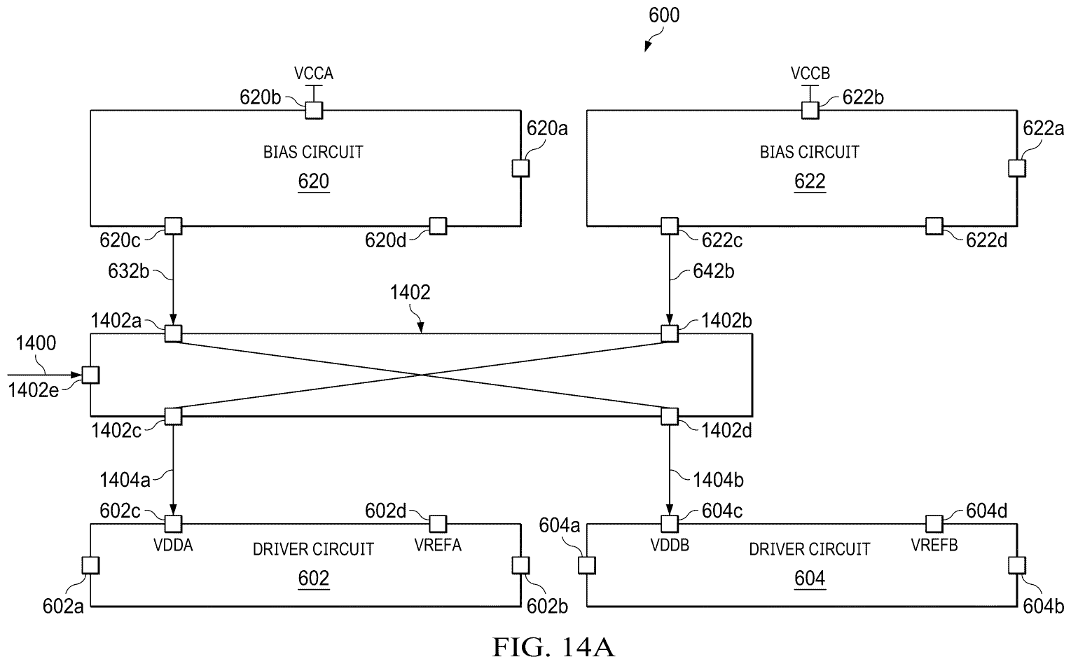

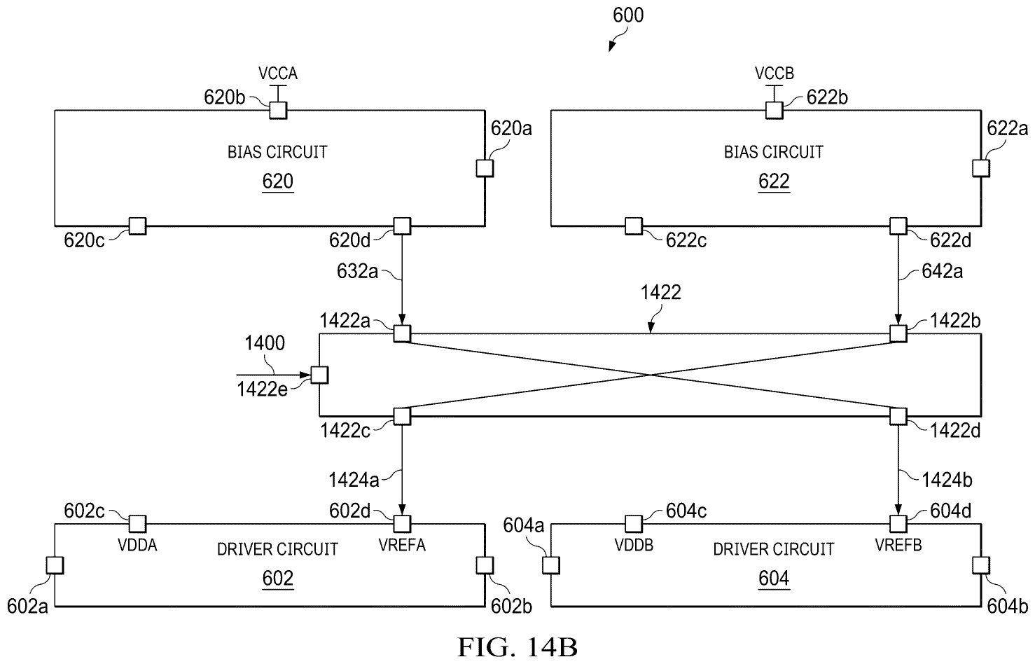

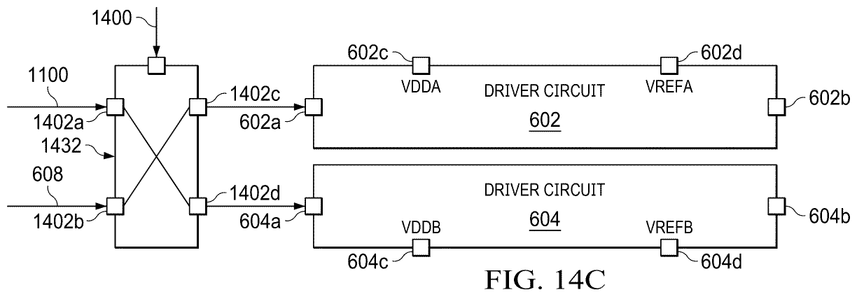

FIGS. 14A, 14B, and 14C are schematics illustrating examples of switch networks that can be part of bidirectional switch driver 600. Referring to FIG. 14A, bidirectional switch 600 can include a switch network 1402. Switch network 1402 has inputs 1402a and 1402b coupled to, respectively, power supply output 620c of bias circuit 620 and power supply output 622c of bias circuit 622. Switch network 1402 has outputs 1402c and 1402d coupled to, respectively, power supply terminal 602c (VDDA) of driver circuit 602 and power supply terminal 604c (VDDB) of driver circuit 604. Switch network 1402 also has a selection input 1402e to receive a crossover detection signal 1400, which indicates whether the voltage difference between current terminals 106 and 116 is positive or negative, or whether the voltage at current terminal 106 exceeds the voltage at current terminal 116.

If the voltage difference is positive, where driver circuit 602 is to provide drive signal 612 with reduced voltage swing, switch network 1402 can provide voltage 632b from bias circuit 620 (e.g., voltage 906 of FIG. 9, voltage 1004 of FIGS. 10 and 11) as voltage 1404a to set the VDDA supply voltage of driver circuit 602. Switch network 1402 can also provide voltage 642b from bias circuit 622 (voltage 928 of FIGS. 9-11) as voltage 1404b to set the VDDB supply voltage of driver circuit 604. On the other hand, if the voltage difference is negative, where driver circuit 604 is to provide drive signal 614 with reduced voltage swing, switch network 1402 can provide voltage 632b from bias circuit 620 (e.g., voltage 906 of FIG. 9, voltage 1004 of FIGS. 10 and 11) as voltage 1404b to set the VDDB supply voltage of driver circuit 604. Switch network 1402 can also provide voltage 642b from bias circuit 622 (voltage 928 of FIGS. 9-11) as voltage 1404a to set the VDDA supply voltage of driver circuit 604.

Referring to FIG. 14B, bidirectional switch 600 can include a switch network 1422. Switch network 1422 has inputs 1422a and 1422b coupled to, respectively, reference output 620d of bias circuit 620 and reference output 622d of bias circuit 622. Switch network 1422 has outputs 1422c and 1422d coupled to, respectively, reference terminal 602d (VREFA) of driver circuit 602 and power supply terminal 604c (VDDB) of driver circuit 604. Switch network 1422 also has a selection input 1422e to receive crossover detection signal 1400, which indicates whether the voltage difference is positive or negative.

If the voltage difference is positive, where driver circuit 602 is to provide drive signal 612 with reduced voltage swing, switch network 1422 can provide voltage 632a from bias circuit 620 (e.g., voltage 906 of FIGS. 9 and 10, voltage 904 of FIG. 11) as voltage 1424a to set the VREFA reference voltage of driver circuit 602. Switch network 1402 can also provide voltage 642a from bias circuit 622 (voltage 924 of FIGS. 9-11) as voltage 1424b to set the VREFB reference voltage of driver circuit 604. On the other hand, if the voltage difference is negative, where driver circuit 604 is to provide drive signal 614 with reduced voltage swing, switch network 1422 can provide voltage 632a from bias circuit 620 (e.g., voltage 906 of FIGS. 9 and 10, voltage 904 of FIG. 11) as voltage 1424b to set the VREFB reference voltage of driver circuit 604. Switch network 1422 can also provide voltage 642a from bias circuit 622 (voltage 924 of FIGS. 9-11) as voltage 1424a to set the VREFA reference voltage of driver circuit 604.

In examples where the top side switch and the low side switch of bidirectional switch 100 receives different driver control signals, such as in the example of FIG. 11, bidirectional switch driver circuit 600 can also include a switch network 1432 coupled to input 602a of driver circuit 602 and input 604a of driver circuit 604. Switch network 1432 can be part of input circuit 606 and has inputs 1432a and 1432b to receive, respectively, static driver control signal 1100 and switching driver control signal 608. Switch network 1432 also has outputs coupled to input 602a of driver circuit 602 and input 604a of driver circuit 604, and a selection input 1432e to receive crossover detection signal 1400. If crossover detection signal 1400 indicates that the voltage difference is positive, switch network 1432 can provide static driver control signal 1100 to input 604a and switching driver control signal 608 to input 604a. If crossover detection signal 1400 indicates that the voltage difference is negative, switch network 1432 can provide static driver control signal 1100 to input 604a and switching driver control signal 608 to input 604a.

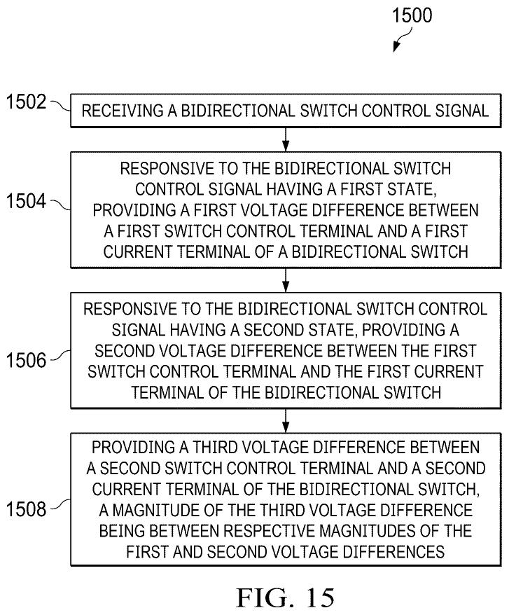

FIG. 15 illustrates a flowchart of an example of a method 1500 of controlling a bidirectional switch, such as bidirectional switch 100. Method 1500 can be performed by, for example, bidirectional switch driver 600.

In operation 1502, bidirectional switch driver 600 receives a bidirectional switch control signal, such as driver control signal 608 that switches between a first state and a second state and sets the on/off state of bidirectional switch 100.

In operation 1504, responsive to the bidirectional switch control signal having a first state, the bidirectional switch driver provides a first voltage difference between a first switch control terminal and a first current terminal of the bidirectional switch. The first switch control terminal and the first current terminal can be of a low side switch device of the bidirectional switch where the first current terminal receives a lower voltage. For example, referring again to FIG. 1, if the voltage at current terminal 106 is higher than the voltage at current terminal 116, switch device 104 is the low side switch and switch device 102 is the high side switch, and bidirectional switch driver 600 can provide the first voltage difference between switch control terminal 118 and current terminal 116. Also, if the voltage at current terminal 106 is lower than the voltage at current terminal 116, switch device 102 is the low side switch and switch device 104 is the high side switch, and bidirectional switch driver 600 can provide the first voltage difference between switch control terminal 108 and current terminal 106. The first voltage difference can be V0 or V1 of FIGS. 7-8.

In operation 1506, responsive to bidirectional switch control signal having a second state, the bidirectional switch driver provides a second voltage difference between the first switch control terminal and the first current terminal of the bidirectional switch. If the first voltage difference is V0 in operation 1504, the second voltage difference can be V1, and if the first voltage difference is V1 in operation 1504, the second voltage difference can be V0.

In operation 1508, the bidirectional switch driver provides a third voltage difference between a second switch control terminal and a second current terminal of the bidirectional switch, a magnitude of the third voltage difference being between respective magnitudes of the first and second voltage differences. The second switch control terminal and the second current terminal are of the high side switch device of the bidirectional switch, which can be one of switch devices 102 or 104 depending on whether the voltage at current terminal 106 is higher or lower than the voltage at current terminal 116 as described above. The third voltage difference can be at V1′ of FIGS. 7-8 and is between V0 and V1.

In some examples, the bidirectional switch driver can provide a static third voltage difference as shown in FIG. 7, which can reduce gate power loss due to switching of the switch devices of the bidirectional switch. In some examples, the bidirectional switch driver can synchronize the switching of the switch control terminals of the bidirectional switch. For example, responsive to the bidirectional switch control signal having the first state, the bidirectional switch driver can provide the first voltage difference (e.g., V1) both between the first switch control terminal and the first current terminal, and between the second switch control terminal and the second current terminal. Also, responsive to the bidirectional switch control signal having the second state, the bidirectional switch driver can provide the second voltage difference (e.g., V0) between the first switch control terminal and the first current terminal, and the third voltage difference (e.g., V1′) between the second switch control terminal and the second current terminal, to improve the on-state resistance of the bidirectional switch. In both arrangements, the voltage applied to the top side switch pGAN gate layer is reduced, which can reduce the amount of hole charge injected by the top side switch pGAN gate layer into the conductive back barrier of the bidirectional switch, which can reduce the off-state leakage current through bidirectional switch.

In this description, the term “couple” may cover connections, communications, or signal paths that enable a functional relationship consistent with this description. For example, if device A generates a signal to control device B to perform an action: (a) in a first example, device A is coupled to device B by direct connection; or (b) in a second example, device A is coupled to device B through intervening component C if intervening component C does not alter the functional relationship between device A and device B, such that device B is controlled by device A via the control signal generated by device A.

Also, in this description, the recitation “based on” means “based at least in part on.” Therefore, if X is based on Y, then X may be a function of Y and any number of other factors.

A device that is “configured to” perform a task or function may be configured (e.g., programmed and/or hardwired) at a time of manufacturing by a manufacturer to perform the function and/or may be configurable (or reconfigurable) by a user after manufacturing to perform the function and/or other additional or alternative functions. The configuring may be through firmware and/or software programming of the device, through a construction and/or layout of hardware components and interconnections of the device, or a combination thereof.

As used herein, the terms “terminal,” “node,” “interconnection,” “pin,” and “lead” are used interchangeably. Unless specifically stated to the contrary, these terms are generally used to mean an interconnection between or a terminus of a device element, a circuit element, an integrated circuit, a device or other electronics or semiconductor component.

A circuit or device that is described herein as including certain components may instead be adapted to be coupled to those components to form the described circuitry or device. For example, a structure described as including one or more semiconductor elements (such as transistors), one or more passive elements (such as resistors, capacitors, and/or inductors), and/or one or more sources (such as voltage and/or current sources) may instead include only the semiconductor elements within a single physical device (e.g., a semiconductor die and/or integrated circuit (IC) package) and may be adapted to be coupled to at least some of the passive elements and/or the sources to form the described structure either at a time of manufacture or after a time of manufacture, for example, by an end-user and/or a third-party.

While the use of particular transistors is described herein, other transistors (or equivalent devices) may be used instead with little or no change to the remaining circuitry. For example, a field effect transistor (“FET”) (such as an n-channel FET (NFET) or a p-channel FET (PFET)), a bipolar junction transistor (BJT—e.g., NPN transistor or PNP transistor), an insulated gate bipolar transistor (IGBT), and/or a junction field effect transistor (JFET) may be used in place of or in conjunction with the devices described herein. The transistors may be depletion mode devices, drain-extended devices, enhancement mode devices, natural transistors or other types of device structure transistors. Furthermore, the devices may be implemented in/over a silicon substrate (Si), a silicon carbide substrate (SiC), a gallium nitride substrate (GaN) or a gallium arsenide substrate (GaAs).

References may be made in the claims to a transistor's control input and its current terminals. In the context of a FET, the control input is the gate, and the current terminals are the drain and source. In the context of a BJT, the control input is the base, and the current terminals are the collector and emitter.

References herein to a FET being “on” or “enabled” means that the conduction channel of the FET is present and drain current may flow through the FET. References herein to a FET being “off” or “disabled” means that the conduction channel is not present so drain current does not flow through the FET. An “off” FET, however, may have current flowing through the transistor's body-diode.

Circuits described herein are reconfigurable to include additional or different components to provide functionality at least partially similar to functionality available prior to the component replacement. Components shown as resistors, unless otherwise stated, are generally representative of any one or more elements coupled in series and/or parallel to provide an amount of impedance represented by the resistor shown. For example, a resistor or capacitor shown and described herein as a single component may instead be multiple resistors or capacitors, respectively, coupled in parallel between the same nodes. For example, a resistor or capacitor shown and described herein as a single component may instead be multiple resistors or capacitors, respectively, coupled in series between the same two nodes as the single resistor or capacitor.

While certain elements of the described examples are included in an integrated circuit and other elements are external to the integrated circuit, in other examples, additional or fewer features may be incorporated into the integrated circuit. In addition, some or all of the features illustrated as being external to the integrated circuit may be included in the integrated circuit and/or some features illustrated as being internal to the integrated circuit may be incorporated outside of the integrated. As used herein, the term “integrated circuit” means one or more circuits that are: (i) incorporated in/over a semiconductor substrate; (ii) incorporated in a single semiconductor package; (iii) incorporated into the same module; and/or (iv) incorporated in/on the same printed circuit board.

Uses of the phrase “ground” in the foregoing description include a chassis ground, an Earth ground, a floating ground, a virtual ground, a digital ground, a common ground, and/or any other form of ground connection applicable to, or suitable for, the teachings of this description.

In this description, unless otherwise stated, “about,” “approximately” or “substantially” preceding a parameter means being within +/−10 percent of that parameter or, if the parameter is zero, a reasonable range of values around zero.

Terms “and” and “or,” as used herein, may include a variety of meanings that are also expected to depend at least in part upon the context in which such terms are used. Typically, “or” if used to associate a list, such as A, B, or C, is intended to mean A, B, and C, here used in the inclusive sense, as well as A, B, or C, here used in the exclusive sense. In addition, the term “one or more” as used herein may be used to describe any feature, structure, or characteristic in the singular or may be used to describe some combination of features, structures, or characteristics. However, it should be noted that this is merely an illustrative example and claimed subject matter is not limited to this example. Furthermore, the term “at least one of” if used to associate a list, such as A, B, or C, can be interpreted to mean A, B, C, or a combination of A, B, and/or C, such as AB, AC, BC, AA, ABC, AAB, ACC, AABBCCC, or the like.

Although various examples have been described in detail, it should be understood that various changes, substitutions, and alterations can be made therein without departing from the scope defined by the appended claims. The devices, structures, materials, and processes discussed above are examples. Various examples may omit, substitute, or add various procedures or components as appropriate. Also, features described with respect to certain examples may be combined in various other examples. Different aspects and elements of the examples may be combined in a similar manner. Also, technology evolves and, thus, many of the elements are examples that do not limit the scope of the disclosure to those specific examples.

Specific details are given in the description on order to provide a thorough understanding of the examples. However, examples may be practiced without these specific details. For example, well-known circuits, processes, systems, structures, and techniques may have been shown without unnecessary detail in order to avoid obscuring the examples. This description provides examples only, and is not intended to limit the scope, applicability, or configuration of the invention. Rather, the preceding description of the examples will provide those skilled in the art with an enabling description for implementing various examples. Various changes may be made in the function and arrangement of elements without departing from the spirit and scope of the present disclosure. Modifications are possible in the described examples, and other examples are possible, within the scope of the claims.

What is claimed is:

1. An apparatus comprising:
a bidirectional switch driver having a control input and a first switch control output and a second switch control output, the bidirectional switch driver including a first driver circuit and a second driver circuit, the first driver circuit having a first driver input coupled to the control input, a first driver output coupled to the first switch control output, and a first reference terminal, the second driver circuit having a second driver input coupled to the control input, a second driver output coupled to the second switch control output, and a second reference terminal, in which:
the first driver circuit configured to, responsive to a state of the control input, provide a first voltage difference or a second voltage difference between the first driver output and the first reference terminal; and
the second driver circuit configured to, responsive to a state of the control input, provide a third voltage difference between the second driver output and the second reference terminal, a magnitude of the third voltage difference being between respective magnitudes of the first and second voltage differences.

2. The apparatus of claim 1, wherein the second driver circuit is configured to provide the third voltage difference between the second driver output and the second reference terminal when the control input has a first state and when the control input has a second state.

3. The apparatus of claim 2, further comprising an input circuit coupled between the control input and the first and second driver inputs, the input circuit configured to receive a switching driver control signal and forward the switching driver control signal to the first driver input and provide a static driver control signal to the second driver input.

4. The apparatus of claim 1, wherein the second driver circuit is configured to:
responsive to the control input having a first state, provide the third voltage difference between the second driver output and the second reference terminal; and
responsive to the control input having a second state, provide the second voltage difference between the second driver output and the second reference terminal.

5. The apparatus of claim 1, wherein the first driver circuit has a first power supply terminal and the second driver circuit has a second power supply terminal;
wherein the bidirectional switch driver includes a first bias circuit and a second bias circuit;
wherein the first bias circuit has a first sense input, a first power supply input, a first power supply output, and a first reference output, the first power supply output coupled to the first power supply terminal, the first reference output coupled to the first reference terminal, the first bias circuit configured to provide a first power supply voltage at the first power supply terminal and a first reference voltage at the first reference terminal;
wherein the second bias circuit having a second sense input, a second power supply input, a second power supply output, and a second reference output, the second power supply output coupled to the second power supply terminal, the second reference output coupled to the second reference terminal, the second bias circuit configured to provide a second supply voltage at the second power supply terminal and a second reference voltage at the second reference terminal; and
wherein at least one of: the first and second supply voltages are different, or the first and second reference voltages are different.

6. The apparatus of claim 5, wherein the first bias circuit includes a voltage offset circuit coupled between the first sense input and the first power supply output and the first reference output; and
wherein the second bias circuit includes a bootstrap circuit having inputs coupled to the second sense input and the second power supply input, and an output coupled to the second power supply output, and the second reference output is coupled to the second sense input.

7. The apparatus of claim 6, wherein the voltage offset circuit includes at least one of: a Zener diode, or a digital-to-analog converter (DAC).

8. The apparatus of claim 5, wherein the first bias circuit includes a voltage offset circuit coupled between the first sense input and the first reference output, and a first bootstrap circuit having inputs coupled to the first power supply input and the first sense input and an output coupled to the first power supply output; and
wherein the second bias circuit includes a second bootstrap circuit having inputs coupled to the second sense input and the second power supply input, and an output coupled to the second power supply output, and the second reference output is coupled to the second sense input.

9. The apparatus of claim 5, wherein the first bias circuit is configured to receive a third supply voltage at the first power supply input and the second bias circuit is configured to receive a fourth supply voltage at the second power supply input, and the third supply voltage is lower than the fourth supply voltage.

10. The apparatus of claim 5, further comprising:
a first switch network having inputs coupled to the first power supply output and the second power supply output and outputs coupled to the first power supply terminal and the second power supply terminal, the first switch network having a first selection input; and
a second switch network having inputs coupled to the first reference output and the second reference output and outputs coupled to the first reference terminal and the second reference terminal, the second switch network having a second selection input coupled to the first selection input.

11. The apparatus of claim 10, further comprising a third switch network having inputs coupled to the control input and a static control signal source and outputs coupled to the first and second driver inputs, the third switch network having a third selection input coupled to the first and second selection inputs.

12. The apparatus of claim 5, further comprising a bidirectional switch having a first current terminal, a second current terminal, a first switch control terminal, and a second switch control terminal, the first current terminal coupled to the first sense input, the second current terminal coupled to the second sense input, the first switch control terminal coupled to the first driver output, and the second switch control terminal coupled to the second driver output.

13. The apparatus of claim 12, wherein the bidirectional switch includes:
a substrate of a first semiconductor material;
a conductive barrier structure on the substrate;
a channel layer of a second semiconductor material on the conductive barrier structure;
a barrier layer on the channel layer, in which the channel layer is between the barrier layer and the conductive barrier structure;
a first gate and a second gate over the barrier layer opposing the channel layer, the first gate coupled to the first switch control terminal, and the second gate coupled to the second switch control terminal;
a first electrode on a first side of the first gate over at least part of the channel layer, the first electrode coupled to the first current terminal; and
a second electrode on a second side of the second gate over at least part of the channel layer, the second electrode coupled to the second current terminal.

14. The apparatus of claim 13, the conductive barrier structure includes one or more of: an Aluminum Gallium Nitride (AlGaN) layer, an Aluminum Nitride (AlN) layer, or Aluminum Indium Nitride (AlInN) layer.

15. The apparatus of claim 13, wherein the first semiconductor material includes silicon, and the second semiconductor material includes Gallium Nitride (GaN).

16. The apparatus of claim 12, wherein the bidirectional switch and the bidirectional switch driver are part of an integrated circuit.

17. The apparatus of claim 12, wherein the bidirectional switch and the bidirectional switch driver are on a semiconductor die.

18. An apparatus comprising:
a first bidirectional switch having a first current terminal and a second current terminal, the first current terminal coupled to an alternating current (AC) terminal, the first bidirectional switch having a first switch control terminal and a second switch control terminal, the second current terminal coupled to a first switching terminal;
a second bidirectional switch having a third current terminal and a fourth current terminal, the third current terminal coupled to the AC terminal, the second bidirectional switch having a third switch control terminal and a fourth switch control terminal, and the fourth current terminal coupled to a second switching terminal;
a first bidirectional switch driver having a first driver input, a first driver output, a first reference terminal, a second driver output, and a second reference terminal, the first driver output coupled to the first switch control terminal, the second driver output coupled to the second switch control terminal, the first reference terminal coupled to the AC terminal, and the second reference terminal coupled to the first switching terminal, the first bidirectional switch driver configured to:
provide a first voltage difference or a second voltage difference between the first driver output and the first reference terminal responsive to a state of the first driver input; and
provide a third voltage difference between the second driver output and the second reference terminal, a magnitude of the third voltage difference being between respective magnitudes of the first and second voltage difference; and
a second bidirectional switch driver having a second driver input, a third driver output, a third reference terminal, a fourth driver output, and a fourth reference terminal, the third driver output coupled to the third switch control terminal, the fourth driver output coupled to the fourth switch control terminal, the third reference terminal coupled to the second switching terminal, and the fourth reference terminal coupled to a ground terminal, the second bidirectional switch driver configured to:
provide the first voltage difference or the second voltage difference between the third driver output and the third reference terminal responsive to a state of the second driver input; and
provide the third voltage difference between the fourth driver output and the fourth reference terminal.

19. The apparatus of claim 18, wherein each of the first and second bidirectional switch drivers has a respective first and second crossover detection input;
wherein the first bidirectional switch driver is configured to:
responsive to the first crossover detection input indicating a positive voltage across the first bidirectional switch, provide the first voltage difference or the second voltage difference between the first driver output and the first reference terminal, and provide the third voltage difference between the second driver output and the second reference terminal; and
responsive to the first crossover detection input indicating a negative voltage across the first bidirectional switch, provide the first voltage difference or the second voltage difference between the second driver output and the second reference terminal, and provide the third voltage difference between the first driver output and the first reference terminal; and
wherein the second bidirectional switch driver is configured to:
responsive to the second crossover detection input indicating a positive voltage across the second bidirectional switch, provide the first voltage difference or the second voltage difference between the third driver output and the first reference terminal, and provide the third voltage difference between the fourth driver output and the fourth reference terminal; and
responsive to the second crossover detection input indicating a negative voltage across the second bidirectional switch, provide the first voltage difference or the second voltage difference between the fourth driver output and the fourth reference terminal, and provide the third voltage difference between the third driver output and the third reference terminal.

20. A method comprising:
receiving a bidirectional switch control signal;
responsive to the bidirectional switch control signal having a first state, providing a first voltage difference between a first switch control terminal and a first current terminal of a bidirectional switch;
responsive to the bidirectional switch control signal having a second state, providing a second voltage difference between the first switch control terminal and the first current terminal of the bidirectional switch; and
providing a third voltage difference between a second switch control terminal and a second current terminal of the bidirectional switch, a magnitude of the third voltage difference being between respective magnitudes of the first and second voltage differences.

21. The method of claim 20, further comprising:
responsive to the bidirectional switch control signal having the first state, providing the third voltage difference between the second switch control terminal and the second current terminal of the bidirectional switch; and
responsive to the bidirectional switch control signal having the second state, providing the second voltage difference between the second switch control terminal and the second current terminal of the bidirectional switch.
